(19) United States
(12) Patent Application Publication
(10) Pub. No.: US 2026/0328801 A1
(43) Pub. Date: Oct. 22, 2026

(54) MECHANICAL FREQUENCY COMB SENSORS FOR HIGH-SENSITIVITY AND STABLE MEASUREMENTS

(71) Applicant: Georgia Tech Research Corporation, Atlanta, GA (US)

(72) Inventors: Azadeh Ansari, Atlanta, GA (US); Yue Zheng, Atlanta, GA (US); Seyyed Mojtaba Hassani Gangaraj, Atlanta, GA (US)

(21) Appl. No.: 19/650,716

(22) Filed: Apr. 17, 2026

Related U.S. Application Data
(60) Provisional application No. 63/790,958, filed on Apr. 18, 2025.

(51) Int. Cl. G01P 15/097; G01P 15/18; H10N 30/853

(52) U.S. Cl. CPC G01P 15/097; G01P 15/18; H10N 30/853

(57) ABSTRACT

An inertial sensor system of the present disclosure comprises a piezoelectric membrane; a single proof-mass attached as a pendulum to the piezoelectric membrane that is configured to cause stress on the piezoelectric membrane and shift mechanical resonance modes of the piezoelectric membrane based on an acceleration direction in an x-axis, y-axis, or z-axis direction; and/or an AC signal source configured to provide an electrical signal to the piezoelectric membrane that produces a mode-locked frequency comb in response to a motion of the piezoelectric membrane caused by the electrical signal, wherein the mode-locked frequency comb is capable of detecting acceleration in the x-axis, y-axis, or z-axis direction.

### CROSS-REFERENCE TO RELATED APPLICATION

This application claims priority to co-pending U.S. provisional application entitled, “Mechanical Frequency Comb Sensors for High-Sensitivity and Stable Measurements,” having application No. 63/790,958, filed Apr. 18, 2025, which is entirely incorporated herein by reference.

### STATEMENT REGARDING FEDERALLY SPONSORED RESEARCH OR DEVELOPMENT

This invention was made with government support under 1944304 awarded by the National Science Foundation. The government has certain rights in the invention.

### TECHNICAL FIELD

The present disclosure is generally related to micromechanical frequency combs.

### BACKGROUND

In the last decade, many research groups have demonstrated mechanical frequency combs in a single resonator platform, using various pumping mechanisms such as m/n:1, or non-degenerate parametric pumping. While it has been theoretically and experimentally demonstrated that a coherent energy transfer from one resonance mode to another (coupled modes or internal resonance) can result in the generation of frequency combs, such combs have generally suffered from small number of comb lines (~10 combs lines), and more importantly, the phase correlation of comb lines have not been studied to date. In order to unlock the full potential of mechanical frequency combs, akin to what optomechanical combs have achieved in precision metrology and spectroscopy, it is required to generate broadband frequency combs (>100 comb lines) and ensure the phase of all comb lines are coherent (i.e. mode-locked).

### BRIEF DESCRIPTION OF THE DRAWINGS

Many aspects of the present disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views.

FIG. 1A presents a schematic of an exemplary multimodal mechanical frequency comb inertial sensor in accordance with various embodiments of the present disclosure.

FIG. 1B illustrates a shift of a resonance frequency and comb spacing due to z-axis acceleration in an exemplary inertial sensor when parametrically pumped by an AC voltage source in accordance with various embodiments of the present disclosure.

FIG. 1C shows a block diagram of an exemplary inertial sensor system in accordance with various embodiments of the present disclosure.

FIG. 2A illustrates wafer fabrication of an inertial sensor in accordance with various embodiments of the present disclosure.

FIGS. 2B-2C shows COMSOL simulation of three resonance modes and their sensitivity to acceleration in x/y and z direction, respectively, in accordance with various embodiments of the present disclosure.

FIG. 3 shows comb spacing as an indicator of an acceleration-induced modal frequency shift in accordance with various embodiments of the present disclosure.

FIG. 4 shows a schematic of mode-locked frequency comb modeling in accordance with various embodiments of the present disclosure.

FIG. 5A shows preliminary simulations of frequency (top) and phase (bottom) of numerical solutions of equations of motion for two coupled modes, showing a large number of phase-coherent comb lines, in accordance with the present disclosure.

FIG. 5B shows simulation results of membrane displacement time response of a phase-coherent frequency comb versus a non-phase coherent frequency comb in accordance with the present disclosure.

FIG. 5C shows the simulation of 10, 50, and 100 phase-coherent comb lines in accordance with the present disclosure.

FIG. 5D shows the simulated velocity of a coherent frequency comb with 50 lines in accordance with the present disclosure.

### DETAILED DESCRIPTION

The present disclosure describes systems and methods for a novel multimodal mechanical frequency comb inertial sensor with extended dynamic range and resilience to external perturbations by generating phase-coherent, broadband frequency combs with extreme size, weight, and power (SWAP) improvement over linear resonant inertial sensors. Thus, a resonant inertial sensor platform may be used for generations of mode-locked frequency combs.

The present disclosure achieves mode locking by targeting the kHz resonance range, because the resonance modes and their harmonics are closer in frequency and closer to the kHz frequency spacings realized in mechanical frequency combs (FCs). This facilitates forming seeds for subsequent energy transfer, nonlinear frequency mixing, and four wave mixing, which coincidentally matches the inertial sensor application space. Mode locking is further achieved by increasing the pumping strength, where it has been shown that discontinuous FCs can merge to form one collective mode-locked FC. When sufficient pump strength is achieved, tuning the pump strength by theoretically and experimentally plotting the Arnold's tongues for different dynamical states will help optimize the pump power and detuning frequency. The nonlinearities and modal coupling are engineered to ensure efficient successive modal coupling is achieved to prevent discontinuous FCs. It must be noted that the two mode-locked FC reports of the existing literature use kHz cantilevers as the comb generation platform.

Traditional resonant-based sensors monitor environmental perturbation by tracking the resonant frequencies of one or multiple resonance modes. However, the sensitivities of those sensors rely on intrinsic material properties, making tuning the sensitivity very challenging. Furthermore, the long term stability of the sensors are compromised due to mechanisms such as aging and drift.

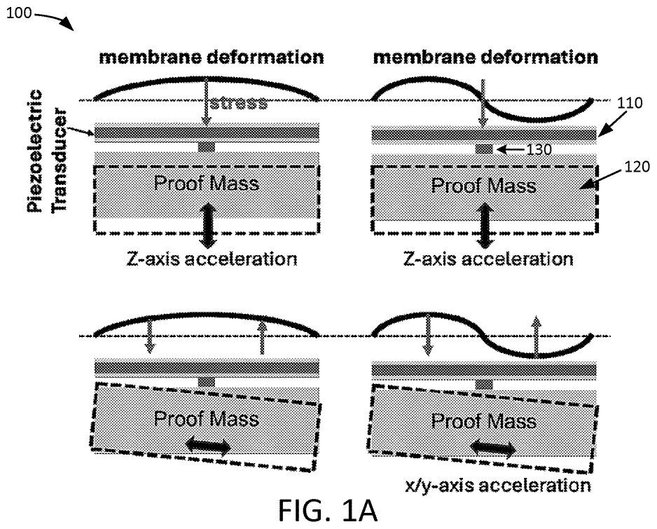

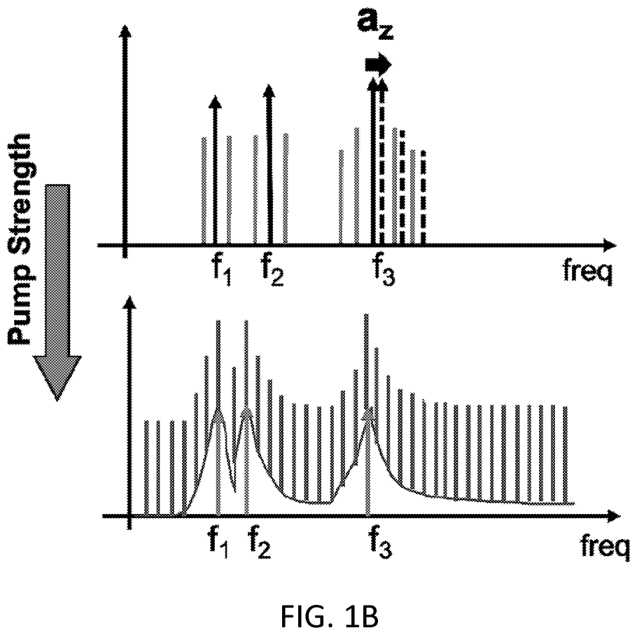

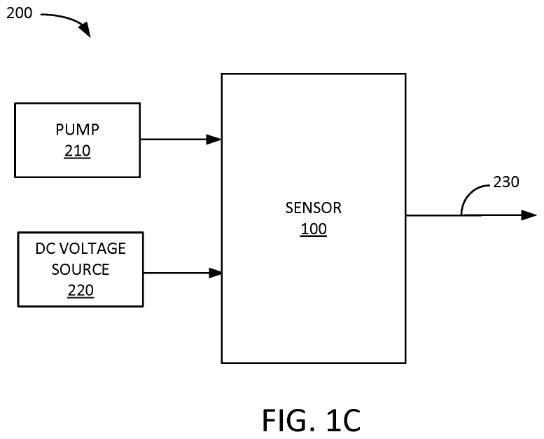

FIG. 1A presents a schematic of an exemplary multimodal mechanical frequency comb inertial sensor 100 in accordance with the present disclosure. In various embodiments, a proof-mass 120 is attached as a pendulum to a piezoelectric membrane 110 which causes the mass 120 to exert stress on the piezoelectric membrane 110 based on an acceleration direction, which will uniquely shift 3 resonance modes of the sensor 100. In various embodiments, the exemplary multimodal mechanical frequency comb inertial sensor 100 is composed of a piezoelectric Al_{0.7}Sc_{0.3}N transducer membrane 110 with a single pendulum proof mass 120 attached. The applied acceleration in x, y, and z direction will induce stress on the membrane 110 and thus uniquely shift the resonance frequencies of multiple membrane modes. The added proof mass 120 will reduce the membrane resonance modes from MHz to KHz range, where the resonance frequency of the inertial sensor can be adjusted by varying the thickness of the proof mass 120, as well as the tether design used to attach the single proof membrane 120 to the piezoelectric membrane 110. In various embodiments, the resonance frequency may be equal to or less than 8 KHz with less than a 500 μm×500 μm footprint. In various embodiments, a three-axis accelerometer can be realized by monitoring the frequency shift of 3 resonance modes, and may be extended to a 6-DoF sensing.

As shown in FIG. 1B, an exemplary z-axis acceleration shifts a resonance frequency (f₃) and comb spacing where discontinuous combs are excited close to each mode when parametrically pumped by an AC voltage source. With sufficient pump strength applied to the sensor 100, a mode-locked, broadband “collective” comb can be achieved, showing resilience to external perturbation due to mode-locking.

Next, FIG. 1C shows a block diagram of an exemplary inertial sensor system 200 of an embodiment of the present disclosure. In the figure, an electrical AC signal from a pump device 210 drives the inertial sensor 100. By applying a signal from a DC voltage source 220 coupled to the inertial sensor 100, the mechanical modes of the piezoelectric membrane 110 of the sensor 100 can be adjusted. The inertial sensor 100 is configured to produce at least one phononic frequency comb at an output 230 in response to a motion of the mechanical resonator 110 caused by the electrical signal in accordance with the present disclosure.

Thus, in accordance with various embodiments of the present disclosure, an exemplary inertial sensor 100 leverages a fine-tooth mechanical frequency comb generated in the mechanical resonator 110 with electrical input/output using parametric pumping, where the perturbation is sensed using the spacing of the frequency comb teeth. By harnessing the nonlinear resonance phenomena from parametric pumping, this approach transcends the sensitivity limitation of a traditional resonant-based solution. The sensitivity can be further amplified by the number of comb fingers. On top of that, the mode-locking and phase coherent nature of these comb fingers make them resilient to external noise (e.g. shock), making these sensors extremely stable compared to the resonant sensor counterparts.

The sensing system incorporates coupled-mode mechanical resonators with high quality (Q) factor, using which mechanical frequency combs are excited via parametric amplification at a pump frequency (fₚᵤₘₚ) near the natural frequency (f₀) or its (sub)harmonics. The comb spacing (Δf) are highly sensitive to external perturbations such as temperature, pressure, or acceleration change, which modulate the nonlinear parametric region of the resonator 110. By tracking the changes in Δf as a function of the perturbation, the sensor system achieves significantly higher sensitivities compared to conventional methods. A wide range of temperature sensitivity can be achieved by adjusting the frequency of the AC pump signal (fₚᵤₘₚ) which also impact the parametric regime hence Δf. Furthermore, the sensitivity performance is scaled by the maximum comb order (N).

The present disclosure considers mode coupling between multiple resonance modes (with and without many-to-many (m/n) relationships), with amplified pump strength to generate mode-locked frequency combs (FCs). Wideband, phase coherent FCs form sharp pulse trains of energy with precise intervals in the time domain, which can significantly improve resilience to drift and external perturbations thanks to the short duration of the pulses that minimize impact from mechanical distortion. The phase locking mechanism renders the sensor 100 resilient to external perturbations by forming a stable vibrational pattern where any perturbation is countered by the collective behavior of all the modes working to maintain phase coherence. Phase coherence leads to higher SNR, and larger number of comb line numbers improves the phase noise thanks to averaging effects, critical to achieve high resolution, resilient and stable combs sensors.

In accordance with various embodiments, an exemplary multimodal mechanical frequency comb inertial sensor 100 takes advantage of efficient piezoelectric transduction and nonlinearities in a thin piezoelectric membrane 110, with a pendulum proof mass 120 attached to (a) realize a six degrees of freedom (6DoF) inertial sensor 100, and (b) lower the membrane mode frequency to kHz, critical for realization of mode-locked, merged, collective mechanical FCs. This single sensor device 100 can resolve x, y, and z-axis acceleration, which can be extended to resolving roll, pitch, yaw (6 DoF).

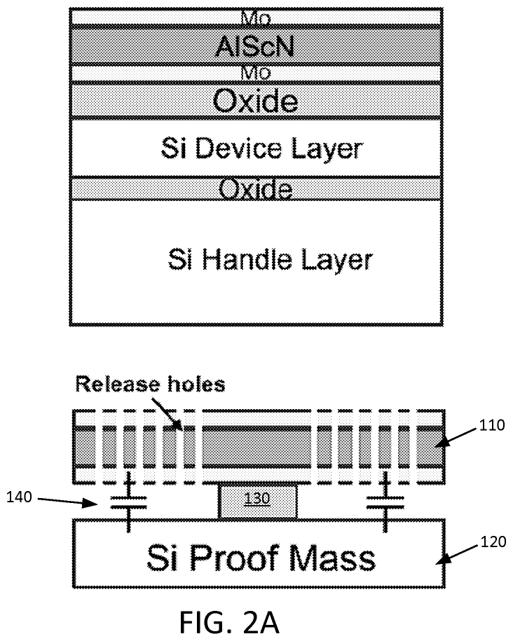

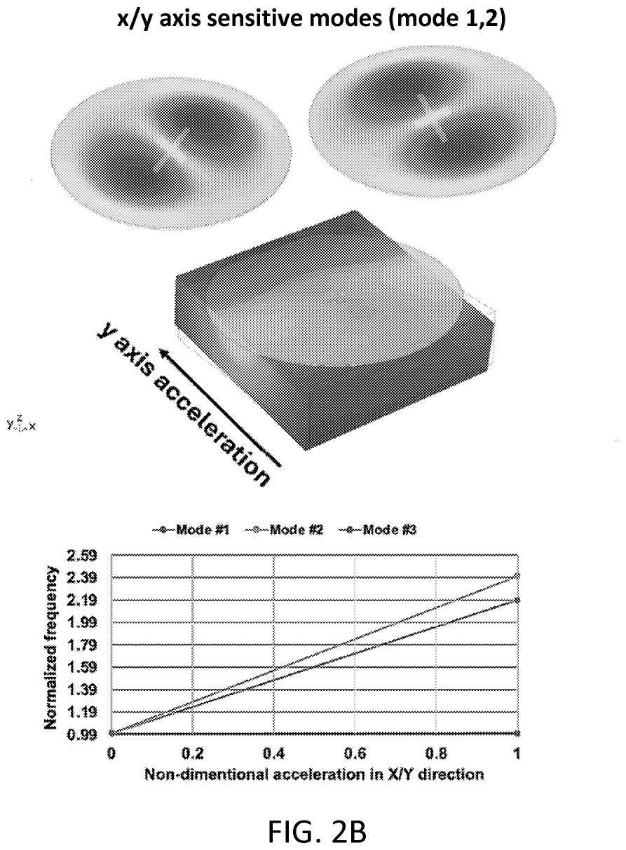

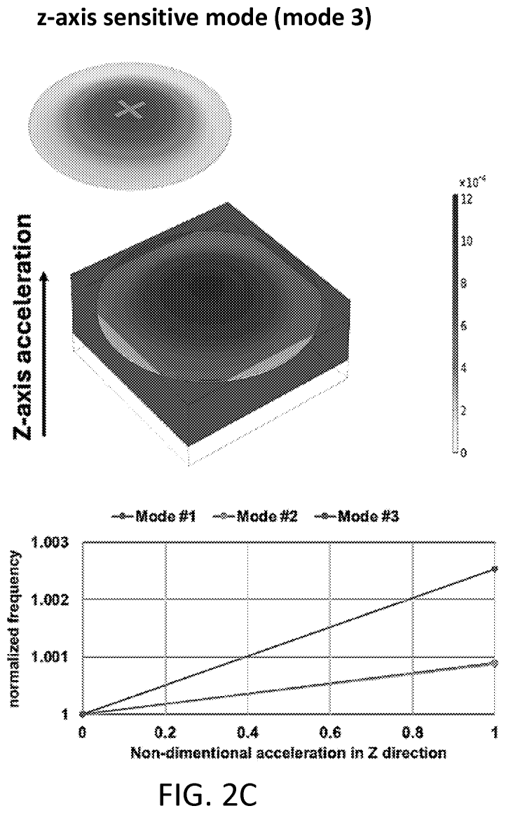

As shown in FIG. 2A, for inertial sensor fabrication, in various embodiments, a piezo stack can be sputtered on an oxide on Si or oxide on SOI wafer. The proof mass 120 can be fabricated from a silicon device layer in an SOI substrate, or the Si handle layer, depending on the thickness requirement. The piezoelectric membrane 110 comprises AlScN and a cross bar suspension device 130 may be fabricated from the oxide layer and patterned using release holes in the piezo stack. Top and bottom electrodes comprising molybdenum (Mo) are positioned next to the piezoelectric membrane 110.

The present disclosure uses electrostatic (capacitance 140 between the bottom electrode and the Si proof mass 120), and DC piezoelectric stress tuning to tune the mechanical resonance modes to yield commensurate relationships postprocessing, if needed, as well as design the resonance modes to ensure large coupling factors.

In various embodiments, multiple resonance modes are excited simultaneously and the shift in each resonance mode is monitored. Instead of a linear operation, a frequency comb is excited in the kHz range with the fundamental sense mode <8 KHz. By using locked-frequency combs, the inertial sensor is resilient to shock and vibration.

In the mechanical FC realm, most reported FCs are not mode locked, and exhibit few comb lines, whose amplitude decays quickly at frequencies away from the resonance mode. While the equidistant mechanical frequency comb lines are interesting tools to amplify the sensitivity of resonant sensors, the phase of the comb lines, that determine the SNR, resolution, resilience, and dynamic range have not been studied to date. Without a mode lock, mechanical FCs do not “unlock” their full potential, and cannot achieve precision metrology and spectroscopy on par with their optical counterparts.

In accordance with various embodiments of the present disclosure, the pendulum proof mass 120 induces stress on the piezoelectric membrane 110, depending on the acceleration axis, electrode placement, and tether design. Similar structures have been realized in existing publications for inertial sensing applications. See D. E. Serrano et al., “Single Proof-Mass Tri-Axial Pendulum Accelerometers Operating in Vacuum,” 2014 IEEE 27th International Conference on Micro Electro Mechanical Systems (MEMS), San Francisco, CA, USA, 2014, pp. 28-31; Xuge Fan et al., “Resonant Transducers Consisting of Graphene Ribbons with Attached Proof Masses for NEMS Sensors,” ACS Applied Nano Materials 2024 7 (1), pp. 102-109. An exemplary design of the present disclosure utilizes Mo/Al_{0.7}Sc_{0.3}N/Mo with <1 μm thickness, sputter-deposited on a Si or SOI wafer to ensure the membrane can be driven at large amplitudes, with strong piezoelectric excitation force, in the presence of large (geometric) duffing nonlinearities. The strong piezoelectric coefficient is important for excitation of phase-coherent frequency combs. Acceleration in the z-direction will create an out-of-place force, translated to the piezoelectric membrane through the tethers that significantly shift the (0,1) resonance mode. On the other hand, the impact of z-axis acceleration on the (1,1) mode is minimal when differentially read out. Similarly, acceleration in the x/y direction will shift (1,1) mode significantly, while the (0,1) mode is insensitive to this stress due to charge cancellation. This scheme provides a multimodal solution to resolve acceleration in x, y and z axes using a single proof mass, and by monitoring three resonance modes.

COMSOL FEA simulations in FIGS. 2B-2C show how applied acceleration in each axis is impacting the 3 resonance modes. The design of the cross bar 130 is configured to minimize the cross-axis sensitivity, and ensure membrane robustness and efficient acceleration-to-stress translation. COMSOL simulations show that proof mass dimensions of 200 μm×200 μm×20 μm with a 500 nm thick, 200 μm diameter AlScN transducer results in resonance frequencies of 20.03 kHz, 20.16 kHz, and 23.9 kHz for x, y, and z modes. The final dimensions can be fine-tuned based on FC generation coupling requirements. In a non-limiting example, in order to achieve <8 kHz fundamental sensing frequency requirement, the proof mass dimension can be increased to 250 μm×250 μm×50 μm. The final resonance frequencies will depend on the piezo stack thickness, as well as the proof mass. Various embodiments may keep the lateral dimension below 500 μm, noting that bulk Si can be used as the proof mass using DRIE process. Various piezoelectrically-transduced resonant accelerometers with sub-micro-gravity noise performance can be implemented, such a capacitive tri-axis accelerometers with a pendulum proof mass, expandable to 6DoF inertial sensing based on the structure shown in U.S. Pat. No. 9,003,882 to Farrokh Ayazi et al., which uses the tri-axis pendulum accelerometers as sensing elements of a single vibrating drive mechanism. Other piezoelectrically-transduced resonant accelerometer with sub-micro-gravity noise performance can also be implemented.

One, two, or more mechanical modes can be involved in the parametric excitation of mechanical frequency combs (e.g. 1:1 through internal resonance; 1/n:1 (subharmonic excitation), 2:1 with f₂=2f₁, or f₁+f₂; and f₁+f₂=f₃, or f₁+f₂+f₃). The beauty of this approach is that there is no need for multiple oscillator circuits to sustain oscillations, which can become very challenging for multimodal readout. Furthermore, parametric pumping can effectively reduce the linewidth, and therefore improve the frequency stability of each comb line, leading to higher sensor resolution.

In various embodiments, various pumping mechanisms can be used to generate broad band phase-locked FCs. It has been shown that commensurate relationships between resonance modes facilitate broadband comb generation. Starting with the single mode z-axis sensitivity measurement, a shift in the (0,1) mode can be obtained, as well as the frequency spacing of the generated combs. This method can also be expanded to x, y measurements, as well as simultaneous excitation of all 3 modes.

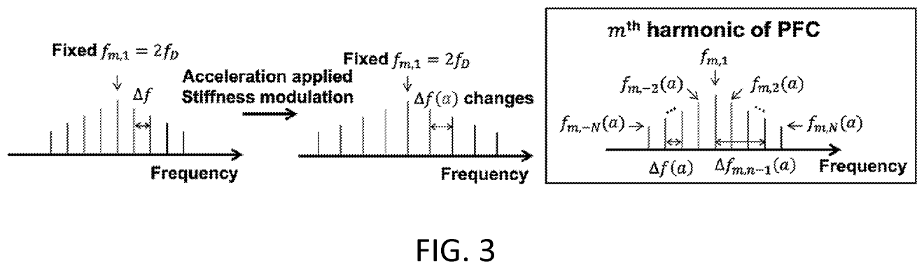

Besides the shift in the comb lines, another indicator of the acceleration-induced modal frequency shift is the comb spacing, as illustrated in FIG. 3, that can be read out with giant sensitivities, amplified by the number of fingers and the detuning parameter. The frequency spacing (repetition rate) of the frequency combs is a strong function of the mechanical resonance modes involved in the excitation of the frequency comb, as well as the detuning parameter and pumping strength. Thus, a frequency shift change can be used to detect x, y, and z acceleration.

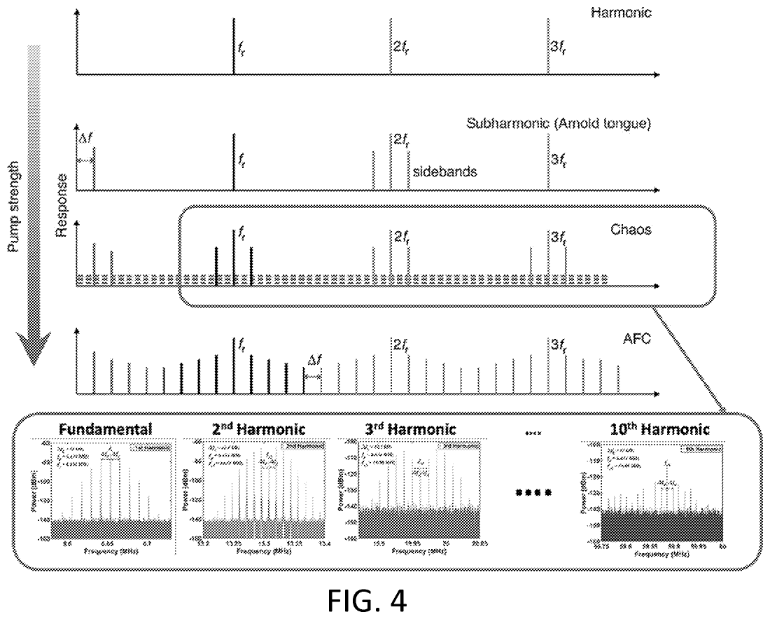

In various embodiments, as illustrated in FIG. 4, systems and methods of the present disclosure can model the piezoelectric transducer and modal coupling using FEA analysis and mode shape overlap integrals, nonlinear terms that facilitate commensurate mode energy transfer, as well as numerical simulations, and set up equations of motion with measured and simulated coupling terms. While most theoretical reports fit the coupling terms, instead of measuring or simulating them, embodiments of the present disclosure evaluate the dependency of the pump strength, Q, nonlinearities, and coupling terms on the mode-locking range, and study the effect dense resonance modes in the vicinity of the parametrically excited modes and their (sub, super) harmonics to achieve mode-locked broadband frequency combs.

For example, the last decade has seen numerous reports on the theoretical analysis and experimental generation of mechanical frequency combs, realized mainly through coupling of two or more resonance modes, internal resonance (IR) or by using parametric excitation through m/n:1 pumping (m, n are integers). Theoretically, the existence of coupling term(s) (i.e. coherent energy transfer from one mode to another), whether using coupled equations of motion, or FPU-α chains, can predict phononic FC generation. However, most reported frequency combs using 1:1 (IR), or 2:1 pumping have been observed in the MHz range with kHz spacings, discontinuous and formed only around a few activated resonance modes or their harmonics with fast decaying amplitudes and a few number of comb lines/sidebands.

Recently phase coherent, kHz-range broadband (>100 combs lines) soliton-like mechanical frequency combs have been realized in cantilevers. Both reports use an optical readout, without integrated transducers. In “Generation of Soliton Frequency Combs in NEMS” by Hamza Mouharrar et al., at Nano Letters 2024 24 (35), pp. 10834-10841, the first 5 bending modes, with commensurate relationships have been excited. It is shown as the pumping strength increases, more number of modes get “activated” and a broader band frequency comb is generated. The dense comb lines generated around each resonance mode are merged, while the resonance modes can still be clearly observed. One of the key factors in achieving soliton-like combs with reasonable pump powers in “Acoustic Frequency Comb Generation on a Composite Diamond/Silicon Microcantilever in Ambient Air” by Z. Zhao et al., at Microsyst Nanoeng (2025), pp. 11-12, and “Generation of Soliton Frequency Combs in NEMS” by Hamza Mouharrar et al., at Nano Letters 2024 24 (35), pp. 10834-10841, is the low resonance frequencies (kHz) compared to the MHz combs. When a harmonic, or subharmonic of an excited mode falls within the phonon bandwidth of another resonance mode, the resonance mode is excited and with nonlinear mixing, sideband generation, and four wave mixing to facilitate broadband comb generation. However, this will not be possible without adequate pump strength. High mechanical quality factors can lower the threshold of the pump required to achieve this dynamical state. For example, in accordance with various embodiments, electrostatic (e.g., capacitance 140 between the bottom electrode and the proof mass 120) and DC piezoelectric stress tuning can be used to adjust the mechanical resonance modes to yield commensurate relationships postprocessing, if needed, as well as design the resonance modes to ensure large coupling factors. Previously, the inventors' have shown formation of combs with equal spacing around the fundamental resonance mode and high order harmonics up to the 10th mode. In various embodiments, a merged phase-coherent comb can be generated by increasing the pump strength (e.g., by impedance matching, using external amplifier or electrical resonant excitation to keep input power <20 dBm), targeting kHz mode, and taking advantage of modal coupling to “stitch” the combs. In various embodiments, an exemplary actuation scheme can excite multiple resonance modes by sequential energy transfer among a set of resonance modes. In particular, direct excitation actuates low-frequency modes, while internal and combination resonances transfer energy from that mode to intermediate (seed) frequencies.

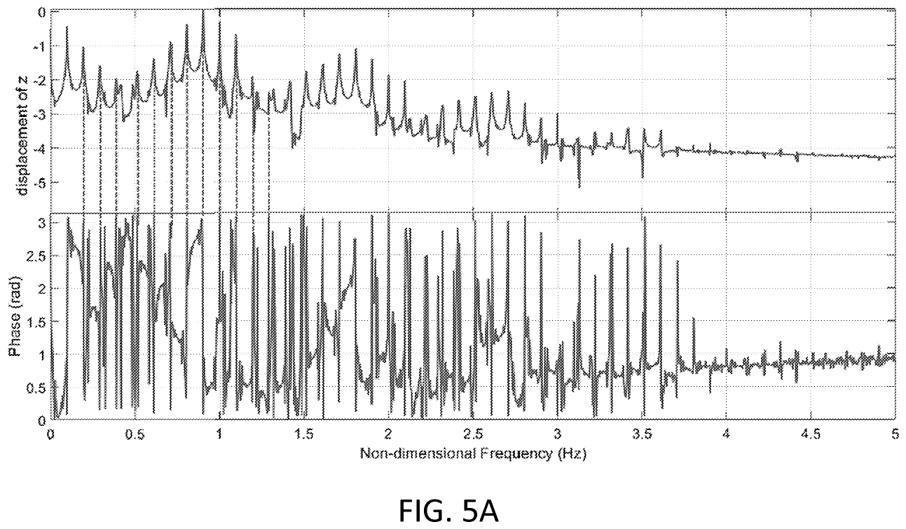

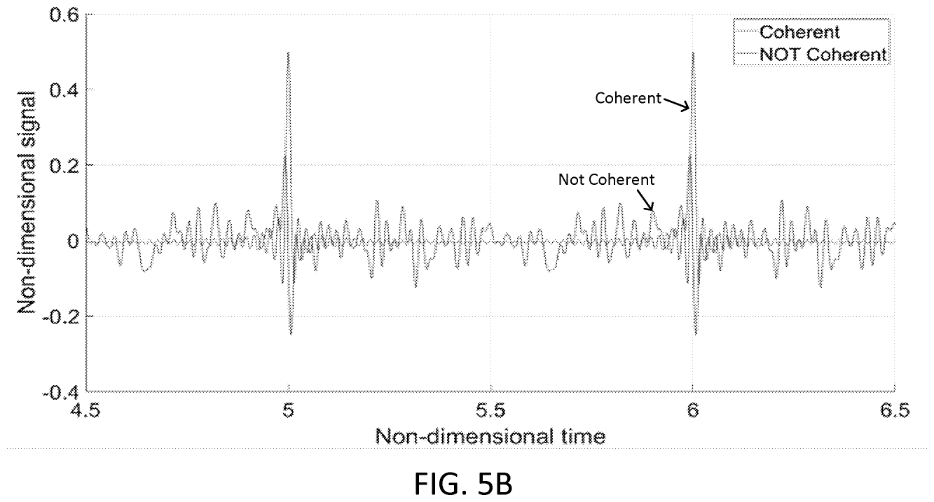

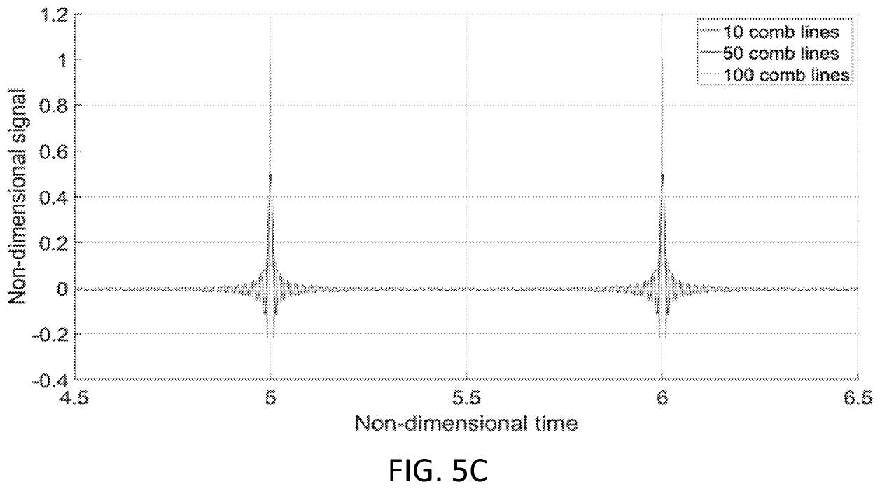

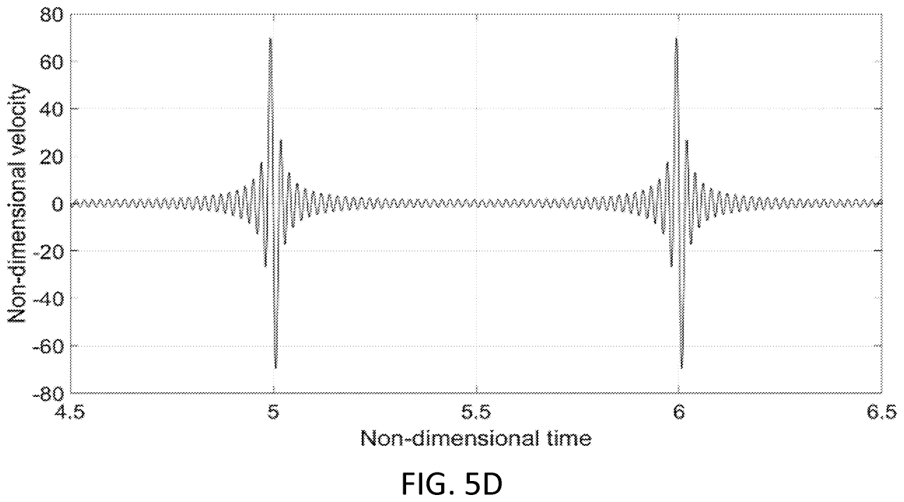

The following preliminary simulation results of mode-locked FCs are presented. Equations 1 and 2 (below) present equations of motion (EoM) for two coupled nonlinear resonance modes (x₁, x₂). Solving them numerically will show that certain combinations of parameters in Equations 1 and 2 lead to the generation of mode-locked FCs, as illustrated in FIGS. 5A-5D.

\ddot{x}₁+ωₓ₁²x₁+2γₓ₁\dot{x}₁+λx₂²x₁+αₓ₁x₁²+βₓ₁x₁³=0, (1)

\ddot{x}₂+ωₓ_{₂}²x₂+2γₓ_{₂}\dot{x}₂+λx₁²x₂+αₓ_{₂}x₂²+βₓ_{₂}x₂³=f cos(ωₚt), (2)

where ωₓ_{_{1,2}} are the modal frequencies, γ is the damping term, and α and β are the quadratic and cubic nonlinearities. Quadratic nonlinearities are common with electrostatic excitation or asymmetries in the stack, while cubic nonlinearities in piezoelectric membranes mainly arise from geometric nonlinearities and are dominant.

FIG. 5A presents preliminary simulations of frequency (top) and phase (bottom) of numerical solutions of Equation 1 for two coupled modes, showing a large number of phase-coherent comb lines.

The parameters leading to mode-locking in FIGS. 5B-5C are listed as follows: ωₓ_{₁}=2π(0.31), ωₓ_{₂}=2π(1), αₓ_{₁}=αₓ_{₂}=10, βₓ_{₁}=βₓ_{₁}=0.1, λ=0.3, 2γₓ=2γ_{z}=0.0001, f=6, ωₚ=2π(1). It must be noted that we chose a 1:3 relationship between the two resonance modes to facilitate mode coupling. However, frequency combs involving a single resonance mode, using IR will also be considered.

To better understand the nature of the FC comb line phase, through time domain analysis, the time domain response has been solved of phase-coherent versus non-coherent combs. FIG. 5B shows simulation results of the membrane displacement time response using

$$x ( t ) = {\sum }_{i = 1}^{N} Acos ( i ω t + {φ}_{i} )$$

of a phase-coherent FC with 50 comb lines versus a non-phase coherent FC, demonstrating that the mode-locked combs have a clear signature in the time domain response and Laser Doppler Velocimetry (LDV) data can be used to study their phase coherence. The phase coherent combs show larger and sharper pulse displacement and cleaner response at the time intervals. Correspondingly, FIG. 5C shows the simulation of 10, 50, and 100 phase-coherent comb lines, clearly showing that increasing the number of comb lines, results in sharper pulse-like waveforms in the resonator displacement x(t). The simulated velocity \dot{x}(t) of a coherent comb with 50 lines is shown in FIG. 5D.

In accordance with various embodiments, a frequency response of the FCs can be characterized using a pump with varying amplitude and detuning frequency to experimentally construct the Arnold's tongues and find the boundaries for FC generation. LDV and digital holographic microscopy (DHM) measurements can be used to directly observe the motion of the membrane 110 regardless of the charge pickup electrode placement. As shown in FIG. 5D, a pulsing behavior in the LDV/DHM response may be an indication of mode-locked comb generation. Within the Arnold's tongue, time-domain (oscilloscope) measurements can also characterize the mode-locking nature of the comb. The phase correlation and phase noise of the comb lines can be directly measured using narrow band filters, lock-in amplifiers, and phase noise analyzers. Ultralow phase noise may be expected due to parametric linewidth narrowing, as well as mode locking. It is expected that a larger number of comb lines and phase coherence (i.e. sharper, higher energy pulses in membrane displacement) will result in higher resilience to external perturbation. In the presence of acceleration, the linear driven mode resonance modes can be characterized to measure frequency sensitivity versus acceleration. For example, when FCs are generated, their comb line, center comb lines, activated modes, and frequency spacing can be tracked versus acceleration as a function of the pump power and detuning. Then, the most sensitive indicator can be chosen to characterize FC sensitivity to multi-axis acceleration. For measuring frequency spacing, dual-comb spectroscopy may be used to mix two combs read out from two sets of electrodes to resolve the frequency spacing change with high precision. It is expected that resilience to shock and vibration may occur in the mode-locked combs, which can be compared against driven resonance mode inertial sensors to prove the resilience of an exemplary multimodal mechanical frequency comb inertial sensor of the present disclosure. With sufficient pump strength, the cross bar 130 becomes completely resilient to a sound perturbation, that would normally cause it to ring if the comb dynamics were not engaged.

Systems and methods of the present disclosure beneficially offer a demonstration of a multimodal resonant multi-axis inertial sensor 100 with a single proof mass 110 to drastically reduce size, weight, and power (SWAP); a demonstration of tri-axis ultrasensitive frequency comb accelerometer by tracking multiple modal frequencies and frequency comb spacings; a demonstration of the comb sensor resistance to external perturbation based on the pump strength; a realization of extreme sensor metric improvements, in terms of stability/resilience (due to mode locking), resolution (due to noise averaging), and dynamic range; and a demonstration of a single inertial sensor with >100 comb lines, that can effectively replace 100 inertial sensors in an array (extreme size/weight reduction)

In summary, systems and methods of various embodiments of the present disclosure use an integrated piezoelectric transduction of a membrane, whose stiffness and nonlinearity can be adjusted via capacitive tuning as an added tuning knob (if required) to tune the resonance frequencies to achieve commensurate relationships. Accordingly, the realization of mode-locking in mechanical FCs with integrated transducers may revolutionize precision metrology and spectroscopy and become the analogues of the optical FCs. Their application goes far beyond inertial sensing, targeting sensing scheme that results in a change in the mass or stiffness of N/MEMS structures, with higher resolution, and more stability thanks to the sharp pulses that for in the time domain. Additionally, injection-locked mechanical FCs are promising candidates for stable timing devices, and frequency synthesizers minimizing drift.

It should be emphasized that the above-described embodiments of the present disclosure are merely possible examples of implementations, merely set forth for a clear understanding of the principles of the disclosure. Many variations and modifications may be made to the above-described embodiment(s) without departing substantially from the principles of the present disclosure. All such modifications and variations are intended to be included herein within the scope of this disclosure and the following claims.

1. An inertial sensor system comprising:
a piezoelectric membrane;
a single proof-mass attached as a pendulum to the piezoelectric membrane that is configured to cause stress on the piezoelectric membrane and shift mechanical resonance modes of the piezoelectric membrane based on an acceleration direction in an x-axis, y-axis, or z-axis direction; and
an AC signal source configured to provide an electrical signal to the piezoelectric membrane that produces a mode-locked frequency comb in response to a motion of the piezoelectric membrane caused by the electrical signal, wherein the mode-locked frequency comb is capable of detecting acceleration in the x-axis, y-axis, or z-axis direction.

2. The system of claim 1, further comprising one or more capacitors connected between a bottom of the piezoelectric membrane and the single proof-mass, wherein the one or more capacitors are configured to adjust the mechanical resonance modes of the piezoelectric membrane.

3. The system of claim 1, wherein a frequency spacing of the mode-locked frequency comb is an indicator of a frequency shift change in the mechanical resonance modes of the piezoelectric membrane.

4. The system of claim 1, wherein the piezoelectric membrane comprises Al_{0.7}Sc_{0.3}N material.

5. The system of claim 1, wherein the mechanical resonance modes are equal to or less than 8 KHz.

6. The system of claim 5, wherein dimensions of the single proof-mass are 250 μm×250 μm×50 μm.

7. The system of claim 1, wherein comb spacing of the mode-locked frequency comb is sensitive to external pertubations.

8. The system of claim 7, wherein the external pertubations include a temperature change, a pressure change, or an acceleration change.

9. The system of claim 1, wherein the mode-locked frequency comb comprises at least 50 phase-coherent comb lines.

10. An inertial sensing method comprising:
attaching a single proof-mass as a pendulum to a piezoelectric membrane that is configured to cause stress on the piezoelectric membrane and shift mechanical resonance modes of the piezoelectric membrane based on an acceleration direction in an x, y, or z-axis direction;
coupling the piezoelectric membrane to an AC voltage source;
driving the piezoelectric membrane with an electrical signal generated by the AC voltage source;
producing a mode-locked frequency comb in response to a motion of the piezoelectric membrane caused by the electrical signal; and
detecting acceleration in the x-axis, y-axis, or z-axis direction from the mode-locked frequency comb.

11. The method of claim 10, further comprising increasing a strength of electrical signal generated by the AC voltage source to form the mode-locked frequency comb by merging discontinuous frequency combs.

12. The method of claim 10, further comprising:
connecting one or more capacitors connected between a bottom of the piezoelectric membrane and the single proof-mass; and
adjusting the mechanical resonance modes of the piezoelectric membrane by tuning a value of the one or more capacitors.

13. The method of claim 10, wherein a frequency spacing of the mode-locked frequency comb is an indicator of a frequency shift change in the mechanical resonance modes of the piezoelectric membrane.

14. The method of claim 13, further comprising realizing a three-axis accelerometer by monitoring the frequency shift change of three mechanical resonance modes of the piezoelectric membrane.

15. The method of claim 10, wherein the piezoelectric membrane comprises Al_{0.7}Sc_{0.3}N material.

16. The method of claim 10, wherein the mechanical resonance modes are equal to or less than 8 KHz.

17. The method of claim 16, wherein dimensions of the single proof-mass are 250 μm×250 μm×50 μm.

18. The method of claim 10, wherein comb spacing of the mode-locked frequency comb is sensitive to external pertubations.

19. The method of claim 18, wherein the external pertubations include a temperature change, a pressure change, or an acceleration change.

20. The method of claim 18, further comprising adjusting a frequency of the electrical signal to change sensitivity of the mode-locked frequency comb.
